(19) United States
(12) Patent Application Publication
(10) Pub. No.: US 2025/0318148 A1
(43) Pub. Date: Oct. 9, 2025

(54) SEMICONDUCTOR DEVICE AND METHOD OF MANUFACTORING THE SAME

(71) Applicant: Samsung Electronics Co., Ltd., Suwon-si (KR)

(72) Inventors: SANGHUN KIM, Suwon-si (KR); Wooahm Kwak, Suwon-si (KR); JEEYONG KIM, Suwon-si (KR); JINHYUK KIM, Suwon-si (KR); Seungkeon Lee, Suwon-si (KR); SEHEE JANG, Suwon-si (KR); Seoyoung Choi, Suwon-si (KR)

(21) Appl. No.: 18/918,669

(22) Filed: Oct. 17, 2024

(30) Foreign Application Priority Data
Apr. 5, 2024 (KR) 10-2024-0046697

(51) Int. Cl. H10B 80/00; H01L 23/00; H01L 29/51; H10B 12/00

(52) U.S. Cl. CPC H10B 80/00; H10B 12/03; H10D 64/685; H01L 24/13; H01L 2224/13023; H01L 2924/1436

(57) ABSTRACT

A method of manufacturing a semiconductor device includes forming a stacked structure including a plurality of sacrificial insulating layers and a plurality of interlayer insulating layers alternately stacked on a substrate, forming a separation structure penetrating the stacked structure, depositing a sacrificial material inside the separation structure, forming a plurality of dummy holes penetrating the stacked structure, and performing a first pullback to remove a first portion of the plurality of sacrificial insulating layers connected to the plurality of dummy holes through the plurality of dummy holes, after the sacrificial material is deposited inside the separation structure.

### CROSS-REFERENCE TO RELATED APPLICATION

This application claims priority and the benefit thereof under 35 U.S.C. § 119 to Korean Patent Application No. 10-2024-0046697, filed on Apr. 5, 2024, in the Korean Intellectual Property Office, the entire disclosure of which is incorporated herein by reference for all purposes.

### BACKGROUND

### 1. Field of the Invention

Various embodiments of the disclosure relate to a semiconductor device and a method of manufacturing the same.

### 2. Description of the Related Art

There is a demand for a semiconductor device capable of storing a large amount of data in an electronic system that requires data storage. Therefore, methods to increase the data storage capacity of a semiconductor device have been studied. For example, one of the methods to increase the data storage capacity of a semiconductor device proposes a semiconductor device including three-dimensionally arranged memory cells instead of two-dimensionally arranged memory cells.

### SUMMARY

In an embodiment, a method of manufacturing a semiconductor device includes forming a stacked structure including a plurality of sacrificial insulating layers and a plurality of interlayer insulating layers alternately stacked on a substrate, forming a separation structure penetrating the stacked structure, depositing a sacrificial material inside the separation structure, forming a plurality of dummy holes penetrating the stacked structure, and performing a first pullback to remove a first portion of the plurality of sacrificial insulating layers connected to the plurality of dummy holes through the plurality of dummy holes, after the sacrificial material is deposited inside the separation structure. According to the manufacturing method described above, the sacrificial material may physically separate nodes between the dummy holes and the separation structures in the process of expanding the dummy holes (e.g., the process of performing a pullback). Accordingly, it is possible to reduce word line bridge defects, form the separation structure and protruding structures to overlap each other, and reduce the collapse of the stacked structure.

In an embodiment, the forming of the separation structure may include forming a plurality of separation holes penetrating the stacked structure, the separation holes arranged in a horizontal direction, and forming the separation structure by expanding the plurality of separation holes in a radial direction so that adjacent separation holes communicate with each other.

In an embodiment, in the first pullback, the sacrificial material deposited inside the separation structure may not be removed.

In an embodiment, the method may further include filling, through the plurality of dummy holes, with an insulating material at positions of the plurality of sacrificial insulating layers removed in the first pullback.

In an embodiment, the method may further include removing the sacrificial material deposited inside the separation structure.

In an embodiment, the method may further include performing a second pullback to remove a second portion of the plurality of sacrificial insulating layers connected to the separation structure through the separation structure.

In an embodiment, the method may further include filling, through the separation structure, with a conductive material at positions of the plurality of sacrificial insulating layers removed in the second pullback.

In an embodiment, the method may further include filling the separation structure with an insulating material.

In an embodiment, the separation structure and the plurality of dummy holes may be filled with a same insulating material.

In an embodiment, the removing of the sacrificial material deposited inside the separation structure may include opening an upper portion of the separation structure, and removing the sacrificial material inside the separation structure through the opened upper portion of the separation structure.

In an embodiment, the stacked structure may include a memory cell array area and a stepped area, and the dummy holes may be formed in the stepped area.

In an embodiment, the plurality of dummy holes may be arranged to form a designated pattern.

In an embodiment, the method may further include forming a cell contact plug penetrating the stacked structure.

In an embodiment, the cell contact plug may be positioned between the plurality of dummy holes.

In an embodiment, a semiconductor device may be manufactured by the method described above.

In an embodiment, a semiconductor device includes a stacked structure including a plurality of gate electrodes and a plurality of interlayer insulating layers alternately stacked on a substrate, a separation structure including a plurality of separation holes penetrating the stacked structure, wherein the separation structure is formed such that separation holes adjacent in a horizontal direction communicate with each other, a plurality of dummy holes penetrating the stacked structure at positions adjacent to the separation structure, and a plurality of protruding structures protruding in a radial direction from the plurality of dummy holes at heights corresponding to the plurality of gate electrodes and touching the separation structure. The separation structure, the plurality of dummy holes, and the plurality of protruding structures may include an insulating material.

In an embodiment, the separation structure and the plurality of protruding structures may be seamlessly and continuously connected based on a vertical cross section of the stacked structure.

In an embodiment, the separation structure and the plurality of protruding structures may be directly connected so that a conductive material may not be positioned therebetween, based on a vertical cross section of the stacked structure.

In an embodiment, an interval between two protruding structures positioned adjacent to each other in a horizontal direction may be less than or equal to 250 nanometers (nm).

In an embodiment, the stacked structure may include a memory cell array area and a stepped area. The separation structure, the plurality of dummy holes, and the plurality of protruding structures may be formed in the stepped area.

The effects of the semiconductor device and the method of manufacturing the same according to various embodiments may not be limited to the above-mentioned effects, and other unmentioned effects may be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram schematically illustrating an electronic system including a semiconductor device according to an example embodiment;

FIG. 2A is a perspective view schematically illustrating an electronic system including a semiconductor device according to an example embodiment;

FIG. 2B is a cross-sectional view schematically illustrating semiconductor packages according to an example embodiment;

FIG. 3A is a plan view of a semiconductor device according to an example embodiment;

FIG. 3B is a partial cross-sectional view of a semiconductor device according to an example embodiment;

FIG. 4 is a plan view illustrating a portion of a semiconductor device according to an example embodiment;

FIGS. 5A and 5B are cross-sectional views of a semiconductor device, taken along line B-B of FIG. 4, according to an example embodiment;

FIG. 6 is a flowchart of a method of manufacturing a semiconductor device according to an example embodiment;

FIG. 7 is a flowchart of an operation of forming a separation structure in a method of manufacturing a semiconductor device according to an example embodiment;

FIGS. 8A, 8B, 9A, 9B, 10A, 10B, 11A, 11B, 12A, 12B, 13A, 13B, 14A, 14B, 15A, 15B, 16A, and 16B are schematic plan views or cross-sectional views of a semiconductor device, illustrating a method of manufacturing a semiconductor device according to an example embodiment;

FIG. 17A is a plan view illustrating a portion of a semiconductor device according to an example embodiment; and

FIG. 17B is a cross-sectional view of a semiconductor device, taken along line L-L of FIG. 17A, according to an example embodiment.

### DETAILED DESCRIPTION

Hereinafter, embodiments will be described in detail with reference to the accompanying drawings. When describing the embodiments with reference to the accompanying drawings, like reference numerals refer to like components, and any repeated description related thereto will be omitted.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

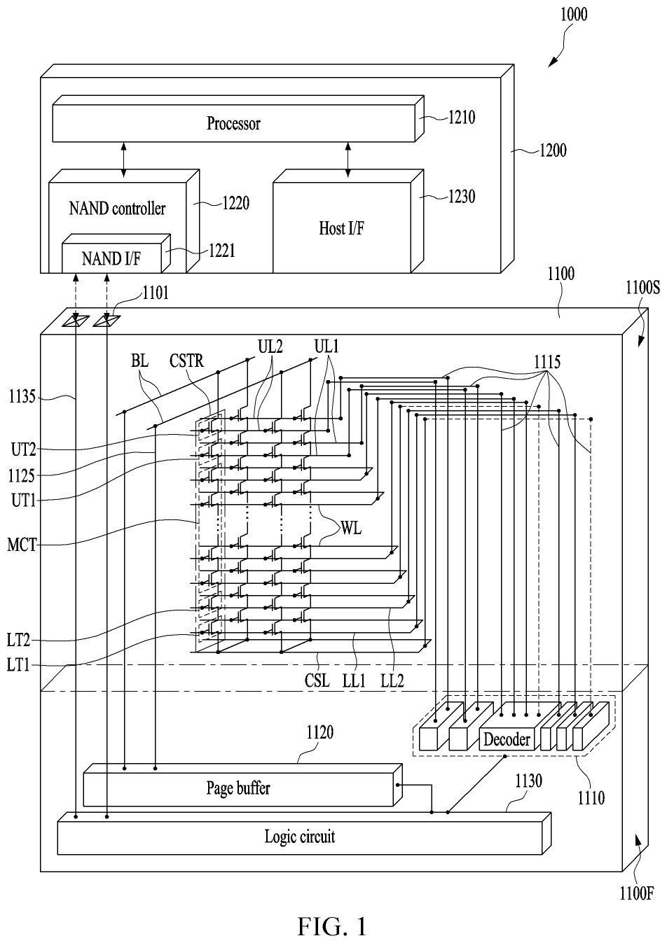

FIG. 1 is a diagram schematically illustrating an electronic system including a semiconductor device according to an example embodiment.

Referring to FIG. 1, according to an embodiment, an electronic system 1000 may include a semiconductor device 1100 and a controller 1200 electrically connected to the semiconductor device 1100. The electronic system 1000 may be a storage device that includes a single or a plurality of semiconductor devices 1100 or may be an electronic device that includes the storage device. For example, the electronic system 1000 may be a solid-state drive (SSD) device, a Universal Serial Bus (USB), a computing system, a medical device, or a communication device, each of which includes a single or a plurality of semiconductor devices 1100.

In an embodiment, the semiconductor device 1100 may be a nonvolatile memory device, such as a NAND flash memory device. The semiconductor device 1100 may include a first structure 1100F and a second structure 1100S on the first structure 1100F. In an embodiment, the first structure 1100F may be arranged next to the second structure 1100S. The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In an embodiment, in the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may vary according to embodiments.

In an embodiment, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In an embodiment, the lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. At least one of the lower erase control transistor LT1 and the upper erase control transistor UT2 may be used for an erasure operation of deleting data stored in the memory cell transistors MCT using a gate induced drain leakage (GIDL) phenomenon.

In an embodiment, the common source line CSL, the first and second gate lower lines LL1 and LL2, the word lines WL, and the first and second gate upper lines UL1 and UL2 may be electrically connected to the decoder circuit 1110 through first connection wires 1115 that extend from the first structure 1100F to the second structure 1100S. The bit lines BL may be electrically connected to the page buffer 1120 through second connection wires 1125 that extend from the first structure 1100F to the second structure 1100S.

In an embodiment, in the first structure 1100F, the decoder circuit 1110 and the page buffer 1120 may perform a control operation on at least one selection memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 that extends from the first structure 1100F to the second structure 1100S.

In an embodiment, the controller 1200 may include a processor 1210, a NAND controller 1220, and a host interface (I/F) 1230. According to an embodiment, the electronic system 1000 may include a plurality of semiconductor devices 1100, and in this case, the controller 1200 may control the plurality of semiconductor devices 1100.

In an embodiment, the processor 1210 may control the overall operation of the electronic system 1000 including the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. Through the NAND interface 1221, a control command to control the semiconductor device 1100, data to be written to the memory cell transistors MCT of the semiconductor device 1100, and/or data to be read from the memory cell transistors MCT of the semiconductor device 1100 may be transmitted. The host interface 1230 may provide a communication function between the electronic system 1000 and an external host. When a control command is received through the host interface 1230 from an external host, the processor 1210 may control the semiconductor device 1100 in response to the control command.

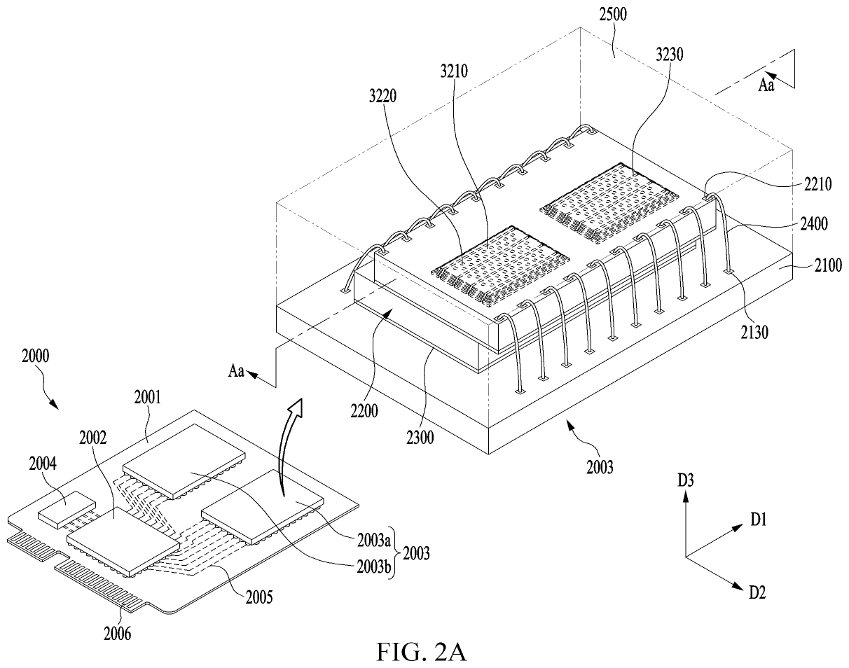

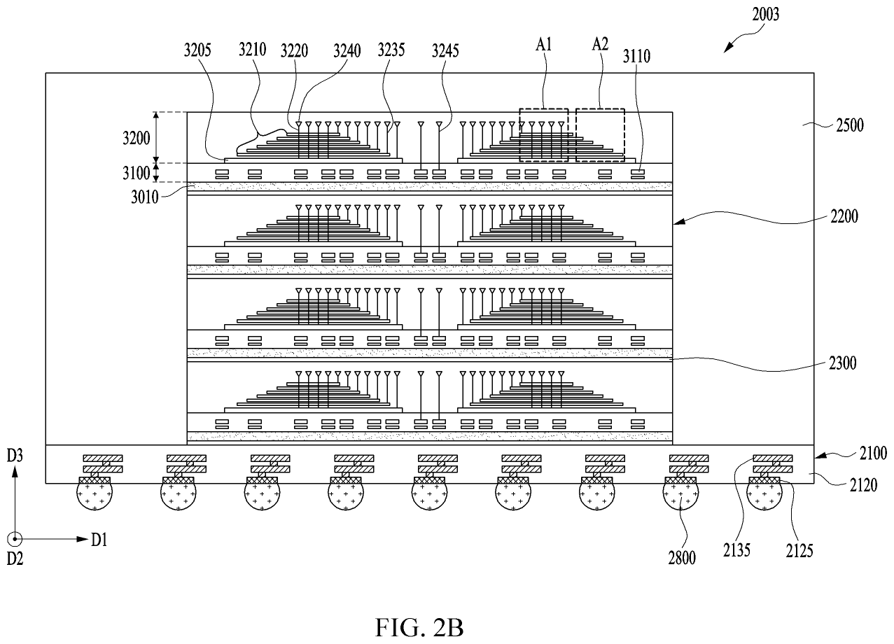

FIG. 2A is a perspective view schematically illustrating an electronic system including a semiconductor device according to an example embodiment of the disclosure.

Referring to FIG. 2A, according to an embodiment, an electronic system 2000 may include a main board 2001, a controller 2002 mounted on the main board 2001, one or more semiconductor packages 2003, and a dynamic random-access memory (DRAM) 2004. The semiconductor packages 2003 and the DRAM 2004 may be connected to the controller 2002 through wiring patterns 2005 formed on the main board 2001.

In an embodiment, the main board 2001 may include a connector 2006 including a plurality of pins that may be coupled to an external host. The number and arrangement of pins on the connector 2006 may vary based on a communication interface between the electronic system 2000 and the external host. In an embodiment, the electronic system 2000 may communicate with the external host according to any one of the interfaces, for example, Universal Serial Bus (USB), Peripheral Component Interconnect Express (PCI Express), Serial Advanced Technology Attachment (SATA), and M-PHY for Universal Flash Storage (UFS). In an embodiment, the electronic system 2000 may operate with the power supplied through the connector 2006 from the external host. The electronic system 2000 may further include a power management integrated circuit (PMIC) to distribute the power supplied from the external host to the controller 2002 and the semiconductor packages 2003.

In an embodiment, the controller 2002 may write data to the semiconductor packages 2003 or read data from the semiconductor packages 2003, thereby increasing the operating speed of the electronic system 2000.

In an embodiment, the DRAM 2004 may be a buffer memory to reduce the speed difference between the external host and the semiconductor packages 2003 that serve as data storage spaces. The DRAM 2004 included in the electronic system 2000 may operate as a kind of cache memory, and may provide a space for temporary data storage in a control operation on the semiconductor packages 2003. When the DRAM 2004 is included in the electronic system 2000, the controller 2002 may include not only a NAND controller for controlling the semiconductor packages 2003, but a DRAM controller for controlling the DRAM 2004.

In an embodiment, the semiconductor packages 2003 may include first and second semiconductor packages 2003a and 2003b that are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, a connection structure 2400 that electrically connects the semiconductor chips 2200 to the package substrate 2100, and a molding layer 2500 that lies on the package substrate 2100 and covers the semiconductor chips 2200 and the connection structure 2400.

In an embodiment, the package substrate 2100 may be a printed circuit board including package upper pads 2130. Each of the semiconductor chips 2200 may include an input/output pad 2210. The input/output pad 2210 may correspond to the input/output pad 1101 of FIG. 1. Each of the semiconductor chips 2200 may include stacked structures 3210 and channel structures 3220. Each of the semiconductor chips 2200 may include a semiconductor device according to an embodiment described below.

In an embodiment, the connection structure 2400 may be a bonding wire that electrically connects the input/output pad 2210 and the package upper pads 2130. Therefore, in each of the first and second semiconductor packages 2003a and 2003b, the semiconductor chips 2200 may be electrically connected to each other in a bonding wire manner, and may be electrically connected to the package upper pads 2130 of the package substrate 2100. According to an embodiment, in each of the first and second semiconductor packages 2003a and 2003b, the semiconductor chips 2200 may be electrically connected to each other through connection structures including through-silicon vias (TSVs) instead of the connection structures 2400 based on the bonding wire manner.

In an embodiment, the controller 2002 and the semiconductor chips 2200 may be included in a single package. In an embodiment, the controller 2002 and the semiconductor chips 2200 may be mounted on a separate interposer substrate other than the main board 2001, and the controller 2002 and the semiconductor chips 2200 may be connected to each other through wires formed on the interposer substrate.

FIG. 2B is a cross-sectional view schematically illustrating semiconductor packages according to an example embodiment. FIG. 2B depicts an embodiment of a semiconductor package of FIG. 2A and conceptually show a section of the semiconductor package of FIG. 2A, taken along line Aa-Aa.

Referring to FIGS. 2A and 2B, in an embodiment, in a semiconductor package 2003, the package substrate 2100 may be a printed circuit board. The package substrate 2100 may include a package substrate body 2120, package upper pads (e.g., the package upper pads 2130 of FIG. 2A) disposed on a top surface of the package substrate body 2120, lower pads 2125 disposed on or exposed through a bottom surface of the package substrate body 2120, and internal wires 2135 electrically connecting the package upper pads 2130 and the lower pads 2125 in the package substrate body 2120. The package upper pads 2130 may be electrically connected to the connection structures 2400. The lower pads 2125 may be connected through conductive connectors 2800 to the wiring patterns 2005 in the main board 2001 of the electronic system 2000 as illustrated in FIG. 2A. The semiconductor package 2003 may include adhesion layers 2300 disposed on the bottom surfaces of the semiconductor chips 2200 and a molding layer 2500 covering the semiconductor chips 2200.

In an embodiment, each of the semiconductor chips 2200 may include a semiconductor substrate 3010, and a first structure 3100 and a second structure 3200 that are sequentially stacked on the semiconductor substrate 3010. The first structure 3100 may include a peripheral circuit area including peripheral wires 3110. The second structure 3200 may include a source structure 3205, a stacked structure 3210 on the source structure 3205, channel structures 3220 and separation structures (e.g., separation structures 3230 of FIG. 2A) that penetrate the stacked structure 3210, bit lines 3240 electrically connected to the channel structures 3220, and cell contact plugs 3235 electrically connected to word lines (e.g., the word lines WL of FIG. 1) of the stacked structure 3210.

In an embodiment, each of the semiconductor chips 2200 may include a through wire 3245 that is electrically connected to the peripheral wires 3110 of the first structure 3100 and extends into the second structure 3200. The through wire 3245 may be disposed on the outer side of the stacked structure 3210 or may be disposed to penetrate the stacked structure 3210. Each of the semiconductor chips 2200 may further include an input/output pad (e.g., the input/output pad 2210 of FIG. 2A) that is electrically connected to the peripheral wires 3110 of the first structure 3100.

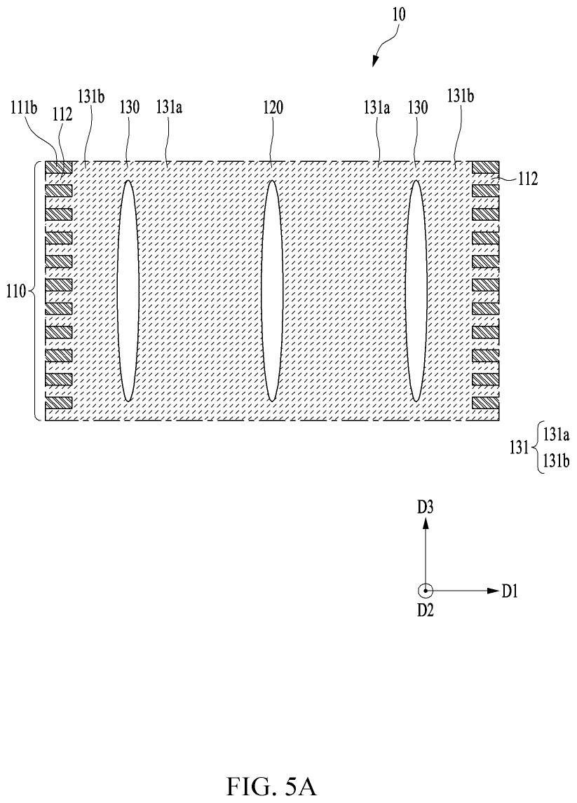

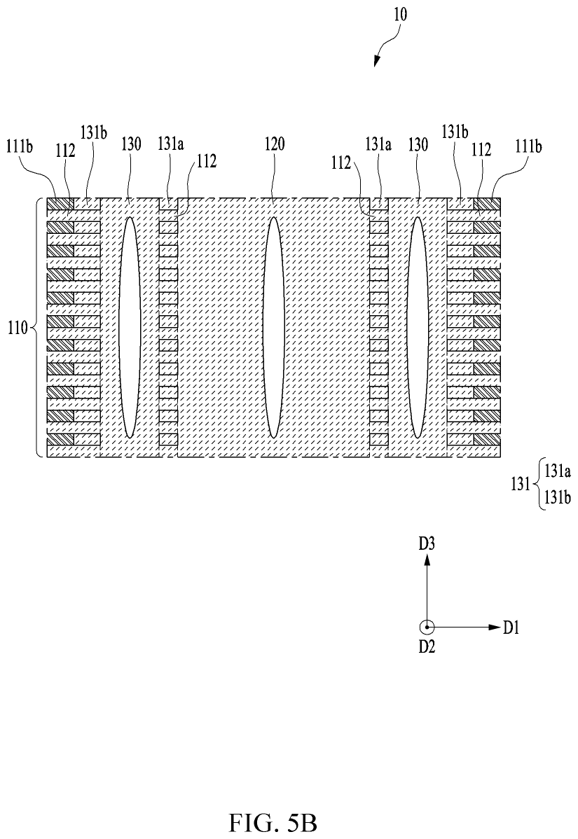

In an embodiment, the stacked structure 3210 may include a cell array area A1 and a stepped area A2. The cell array area A1 may be an area where gate electrodes (e.g., gate electrodes 111b of FIG. 5B) and interlayer insulating layers (e.g., interlayer insulating layer 112 of FIG. 5B) are alternately stacked in the vertical direction (e.g., D3) and the channel structures 3220 are formed. The stepped area A2 may be an area where the gate electrodes 111b extend while forming a staircase shape. For example, the stepped area A2 may be arranged outside the cell array area A1. The stepped area A2 may be an area where pad portions are provided to connect the gate electrodes 111b forming the staircase shape to the cell contact plugs 3235.

In an embodiment, the semiconductor chips 2200 may be electrically connected to each other by connection structures (e.g., the connection structures 2400 of FIG. 2A) in the form of bonding wires. In an embodiment, a plurality of semiconductor chips in one semiconductor package may be electrically connected to each other by connection structures including through silicon vias (TSVs).

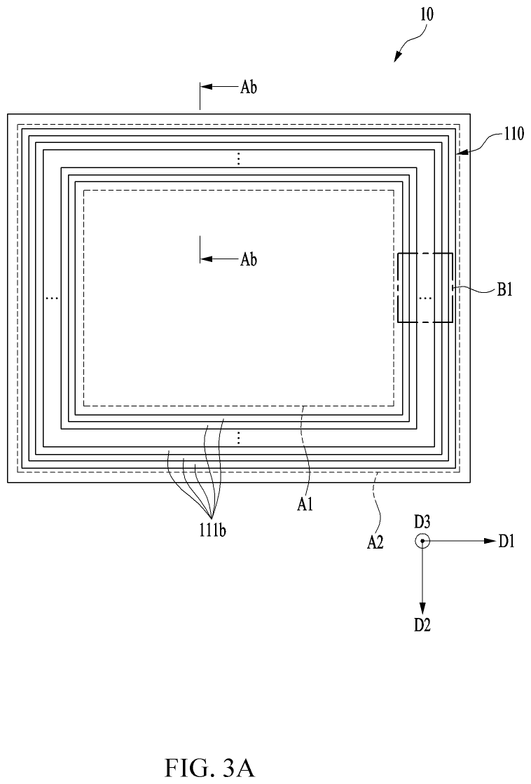

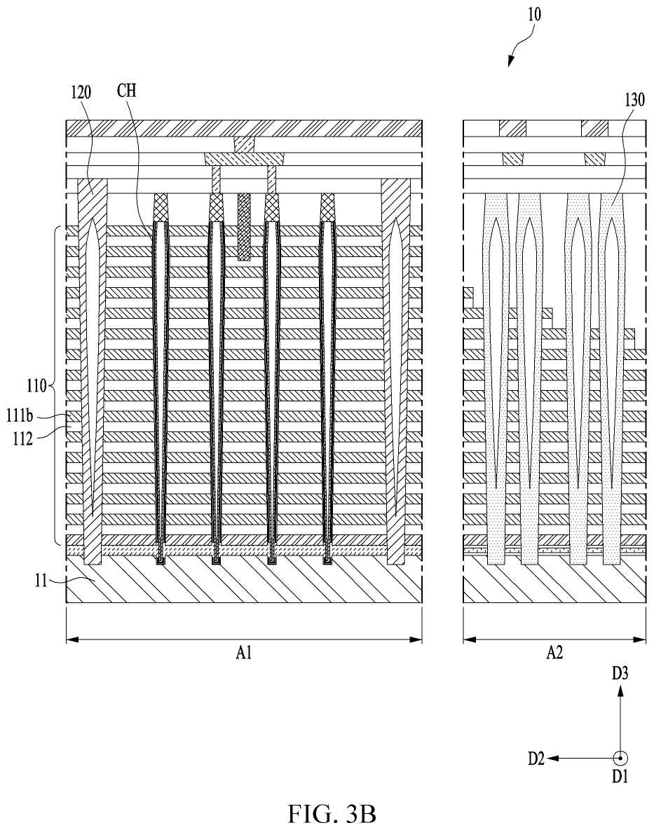

FIG. 3A is a plan view of a semiconductor device according to an example embodiment. FIG. 3A schematically illustrates the layout of the semiconductor device, in a plan view. FIG. 3B is a partial cross-sectional view of the semiconductor device according to an example embodiment. FIG. 3B conceptually illustrates an area cut along line Ab-Ab of FIG. 3A. The semiconductor device 10 may correspond to the semiconductor chips 2200.

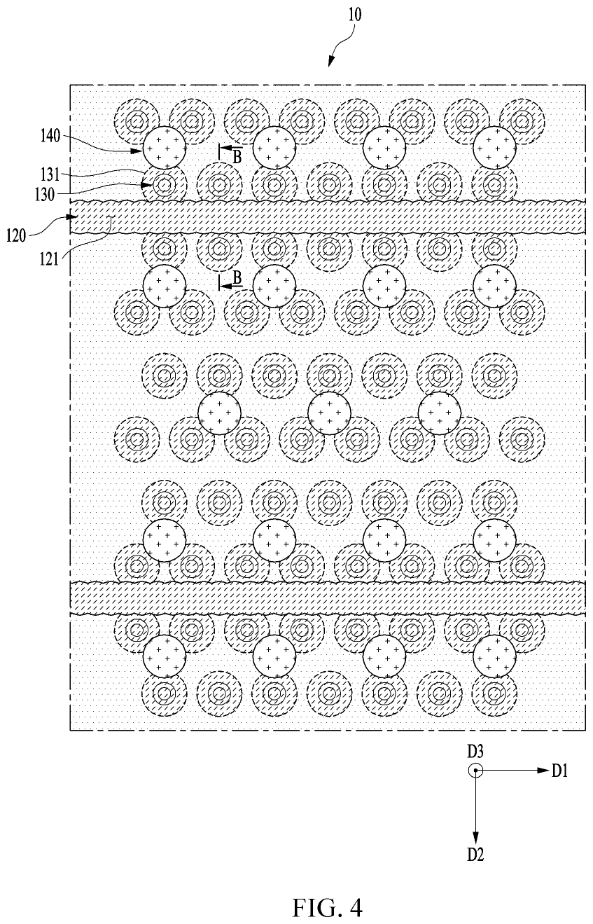

In an embodiment, referring to FIGS. 3A and 3B, a semiconductor device 10 may include a substrate 11, a stacked structure 110 including interlayer insulating layers 112 and gate electrodes 111b alternately stacked on the substrate 11, channel structures CH (e.g., the channel structures 3220 of FIG. 2B) and dummy holes 130 penetrating the stacked structure 110, and a separation structure 120 penetrating the stacked structure 110 and extending in one direction (e.g., D1). The semiconductor device 10 may provide a cell array area A1 where memory cell arrays including the gate electrodes 111b and the channel structures CH are arranged. The stacked structure 110 may include the cell array area A1 and a stepped area A2 surrounding at least one side of the cell array area A1, in a plan view. The cell array area A1 may be an area where the gate electrodes 111b are stacked to be spaced apart in the vertical direction (e.g., D3) and the channel structures CH are arranged. The stepped area A2 may be an area where the gate electrodes 111b extend while forming a staircase shape. The stepped area A2 may be arranged to surround the memory cell array area A1, in a plan view. The stepped area A2 may be an area where the gate electrodes 111b in the staircase shape are connected to cell contact plugs (e.g., cell contact plugs 140 of FIG. 4).

In an embodiment, the gate electrodes 111b may be arranged to be separated from each other by the separation structure 120 extending in one direction. For example, gate electrodes 111b between a pair of separation structures 120 may form a single memory block. However, this is merely an example, and the scope of the memory block is not limited thereto.

In an embodiment, the channel structures CH may each form a single memory cell string, and may be arranged to be spaced apart from each other while forming rows and columns in the cell array area A1. For example, when viewed in plan view, the channel structures CH may be arranged to form a grid pattern or arranged in a zigzag shape in one direction.

In an embodiment, the dummy holes 130 may penetrate the stacked structure 110 in the stepped area A2. For example, the dummy holes 130 may penetrate the gate electrodes 111b in the stepped area A2. The dummy holes 130 may extend through the gate electrodes 111b to the substrate 11. For example, lower surfaces of the dummy holes 130 may be at a lower level than an upper surface of the substrate 11. For example, the dummy holes 130 may be arranged to be spaced apart from each other while forming rows and columns, similar to the channel structures CH, and may be arranged to form a grid pattern or arranged in a zigzag shape in one direction. The dummy holes 130 may not perform a practical function when the semiconductor device 10 operates. A portion of the channel structures CH disposed adjacent to the stepped area A2 may be dummy channel structures. The dummy holes 130 may include an insulating material, for example, at least one of silicon oxide, silicon nitride, and silicon oxynitride. Seams or voids may be present inside an insulating layer forming the dummy holes 130. The dummy holes 130 may prevent the stacked structure 110 from tilting or collapsing, thereby improving the structural stability of the stacked structure 110.

FIG. 4 is a plan view illustrating a portion of a semiconductor device according to an example embodiment. FIG. 4 is a plan view of an area B1 of FIG. 3A. For example, FIG. 4 may be a plan view of a stepped area (e.g., the stepped area A2 of FIGS. 2B and 3A) in a semiconductor device according to an example embodiment. FIGS. 5A and 5B are cross-sectional views of the semiconductor device, taken along line B-B of FIG. 4, according to an example embodiment. FIG. 5B has lines added to the boundaries of the components of FIG. 5A for ease of description, and may be understood as substantially the same drawing as FIG. 5A.

Referring to FIGS. 4, 5A, and 5B, the semiconductor device 10 (e.g., the semiconductor chips 2200 of FIG. 2B) according to an embodiment may include the stacked structure 110, the separation structure 120, the dummy holes 130, protruding structures 131, and the cell contact plugs 140. For example, the semiconductor device 10 may be a vertical NAND flash memory device. However, this is merely an example, and the type of semiconductor device 10 is not limited thereto.

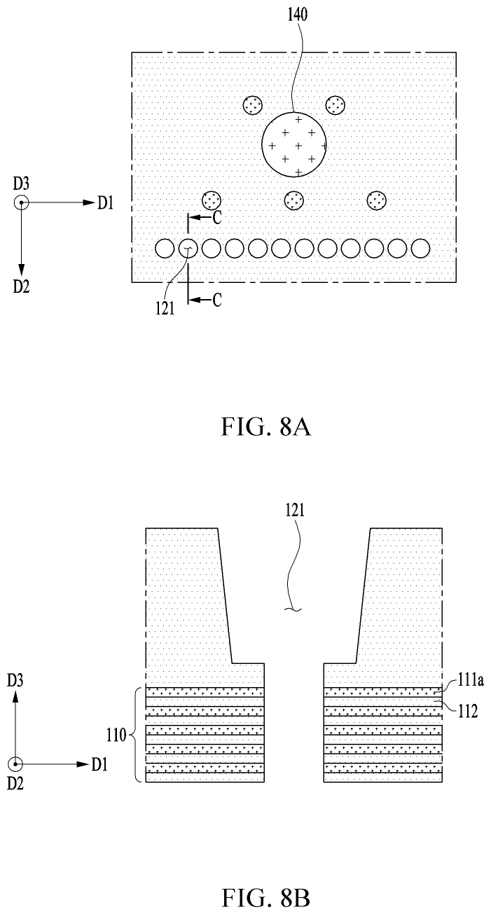

In an embodiment, the stacked structure 110 (e.g., the stacked structure 3210 of FIG. 2B) may be stacked on a substrate (e.g., the semiconductor substrate 3010 of FIG. 2B or the substrate 11 of FIG. 3B). The stacked structure 110 may include a plurality of gate electrodes 111b and a plurality of interlayer insulating layers 112 alternately stacked in the vertical direction D3. The plurality of gate electrodes 111b and the plurality of interlayer insulating layers 112 may extend in the horizontal directions D1 and D2. The gate electrodes 111b may include a conductive material. For example, the gate electrodes 111b may include at least any one of a doped semiconductor (e.g., doped silicon), a conductive metal (e.g., tungsten, copper, molybdenum, and/or aluminum), a conductive metal nitride (e.g., titanium nitride and/or tantalum nitride), or a transition metal (e.g., titanium and/or tantalum). However, these are merely examples, and the material of the gate electrodes 111b is not limited thereto. The gate electrodes 111b may be used as the word lines WL, gate upper lines UL1 and UL2, and/or gate lower lines LL1 and LL2 described with reference to FIG. 1. Each of the plurality of interlayer insulating layers 112 may be positioned between two adjacent gate electrodes 111b. The interlayer insulating layers 112 may include an insulating material. For example, the interlayer insulating layers 112 may include at least any one of silicon oxide, silicon nitride, or silicon oxynitride. However, these are merely examples, and the material of the interlayer insulating layers 112 is not limited thereto. Meanwhile, in the process of the manufacturing semiconductor device 10, the stacked structure 110 may include a plurality of sacrificial insulating layers (e.g., sacrificial insulating layer 111a of FIG. 8B) and the plurality of interlayer insulating layers 112 alternately stacked in the vertical direction D3. The sacrificial insulating layers 111a may be substituted with the gate electrodes 111b through a process to be described later.

In an embodiment, the separation structure 120 (e.g., the separation structure 3230 of FIG. 2A) may penetrate the stacked structure 110 in the vertical direction D3. For example, the separation structure 120 may be formed over a cell array area (e.g., the cell array area A1 of FIGS. 2B and 3A) and a stepped area (e.g., the stepped area A2 of FIGS. 2B and 3A). The separation structure 120 may be formed longitudinally in a first horizontal direction (e.g., D1). For example, a plurality of separation structures 120 may be formed. The plurality of separation structures 120 may be positioned to be spaced apart from each other by a designated distance in a second horizontal direction (e.g., D2). The separation structure 120 may include a plurality of separation holes 121 penetrating the stacked structure 110. The plurality of separation holes 121 may be arranged in the first horizontal direction (e.g., D1). The plurality of separation holes 121 may overlap each other so as to communicate with each other in the first horizontal direction (e.g., D1). For example, the separation structure 120 may be formed by expanding the separation holes 121 so that separation holes 121 positioned adjacent to each other in the first horizontal direction (e.g., D1) may communicate with each other. The separation structure 120 may be filled with an insulating material (e.g., silicon oxide). In the process of filling the separation structure 120 with an insulating material, seams or voids may be formed inside the separation structure 120. However, this is merely an example, and the structure, shape, and/or method of forming the separation structure 120 are not limited thereto. For example, the separation structure 120 may be formed as a single linear structure formed in the first horizontal direction (e.g., D1). The separation structure 120 may be used, in the process of manufacturing the semiconductor device 10, as a path to remove the sacrificial insulating layers (e.g., the sacrificial insulating layers 111a of FIG. 8A) of the stacked structure 110 and form the gate electrodes 111b at the positions from which the sacrificial insulating layers 111a are removed.

In an embodiment, the dummy holes 130 may penetrate the stacked structure 110 in the vertical direction D3. A plurality of dummy holes 130 may be formed. For example, the plurality of dummy holes 130 may be arranged to form a designated pattern. However, the pattern shown in FIG. 4 is merely an example, and the pattern in which the plurality of dummy holes 130 are arranged is not limited thereto. At least a portion of the plurality of dummy holes 130 may be positioned adjacent to the separation structure 120. The dummy holes 130 may be filled with an insulating material (e.g., silicon oxide). In the process of filling the dummy holes 130 with an insulating material, seams or voids may be formed inside the dummy holes 130. For example, the dummy holes 130 may be formed in the stepped area (e.g., the stepped area A2 of FIGS. 2B and 3A). The dummy holes 130 may serve to support the stacked structure 110 to prevent the structure from collapsing in the process of manufacturing the semiconductor device 10.

In an embodiment, the protruding structures 131 may be formed by extending from the dummy holes 130 in the radial direction. For example, the protruding structures 131 may protrude from the dummy holes 130 in the radial direction. For example, the protruding structures 131 may be understood as substantially disk-shaped structures that protrude from the dummy holes 130 in the radial direction. However, this is merely an example, and the shape of the protruding structures 131 is not limited thereto. For example, the protruding structures 131 may not have a complete disk shape, and may have a disk shape with a portion removed. For example, a portion (e.g., 131a of FIG. 5) of a protruding structure 131 may have a relatively small radius compared to another portion (e.g., 131b of FIG. 5). For example, in the process of forming the protruding structures 131 by expanding the protruding structures 131 from the dummy holes 130 in the radial direction, a portion (e.g., portion 131a of FIG. 5) touching an ambient structure (e.g., the separation structure 120) may have a short radius compared to another portion (e.g., portion 131b of FIG. 5). For example, the protruding structures 131 may be formed in the stepped area (e.g., the stepped area A2 of FIGS. 2B and 3A). A plurality of protruding structures 131 may be formed for a single dummy hole 130. The plurality of protruding structures 131 may be positioned to be spaced apart in the vertical direction D3 with respect to one dummy hole 130. For example, each of the plurality of protruding structures 131 may be positioned at a height corresponding to each of the plurality of gate electrodes 111b. The protruding structures 131 may touch the separation structure 120. The protruding structures 131 may be filled with an insulating material (e.g., silicon oxide). For example, in the process of manufacturing the semiconductor device 10, the protruding structures 131 may be formed by filling with an insulating material at the positions from which a portion of the sacrificial insulating layers (e.g., the sacrificial insulating layer 111a of FIG. 8B) are removed. In the process of filling the protruding structures 131 with an insulating material, seams or voids may be formed inside the protruding structures 131. The interval between two protruding structures 131 positioned adjacent to each other in the horizontal directions (e.g., D1 and D2) may be less than or equal to 250 nanometers (nm). However, this is merely an example, and the interval between two protruding structures 131 is not limited thereto. The protruding structures 131 may serve to support the stacked structure 110 to prevent the structure from collapsing in the process of manufacturing the semiconductor device 10.

In an embodiment, the cell contact plugs 140 (e.g., the cell contact plugs 3235 of FIG. 2B) may penetrate the stacked structure 110 in the vertical direction D3. For example, the cell contact plugs 140 may be formed in the stepped area (e.g., the stepped area A2 of FIGS. 2B and 3A). A plurality of cell contact plugs 140 may be formed. The lower end portions of the plurality of cell contact plugs 140 may be electrically connected to the pad portions of the plurality of gate electrodes 111b, respectively. The upper end portions of the plurality of cell contact plugs 140 may be electrically connected to wires and/or contacts formed on the upper end portions of the semiconductor device 10. A cell contact plug 140 may be positioned between a plurality of dummy holes 130. For example, as shown in FIG. 4, a cell contact plug 140 may be positioned in the central portion of the area formed by three adjacent dummy holes 130. However, this is merely an example, and the position of the cell contact plug 140 is not limited thereto.

In an embodiment, referring to FIG. 5A, based on the cross-section in the vertical direction D3 of the stacked structure 110, the separation structure 120, the plurality of protruding structures 131, and the plurality of dummy holes 130 may be substantially seamlessly and continuously connected. Since the separation structure 120, the plurality of protruding structures 131, and the plurality of dummy holes 130 are filled with substantially the same insulating material (e.g., silicon oxide), it may seem that there is no boundary therebetween when the cross section of the stacked structure 110 in the vertical direction D3 is viewed. For example, based on the cross section of the stacked structure 110 in the vertical direction D3, one portion 131a of a protruding structure 131 may contact the separation structure 120, and the other portion 131b of the protruding structure 131 may contact a gate electrode 111b. FIG. 5B has lines added to the boundaries of the components of FIG. 5A for ease of description. Referring to FIG. 5B, the separation structure 120 and the plurality of protruding structures 131 may be directly connected so that a conductive material may not be positioned therebetween, based on the cross section of the stacked structure 110 in the vertical direction D3. For example, based on a single protruding structure 131, one portion 131a of the protruding structure 131 may contact the separation structure 120, and the other portion 131b of the protruding structure 131 may contact a gate electrode 111b. For example, based on a single protruding structure 131, the horizontal width (e.g., radius) of one portion 131a of the protruding structure 131 positioned adjacent to the separation structure 120 may be shorter than the horizontal width (e.g., radius) of the other portion 131b of the protruding structure 131, positioned on the opposite side of the separation structure 120.

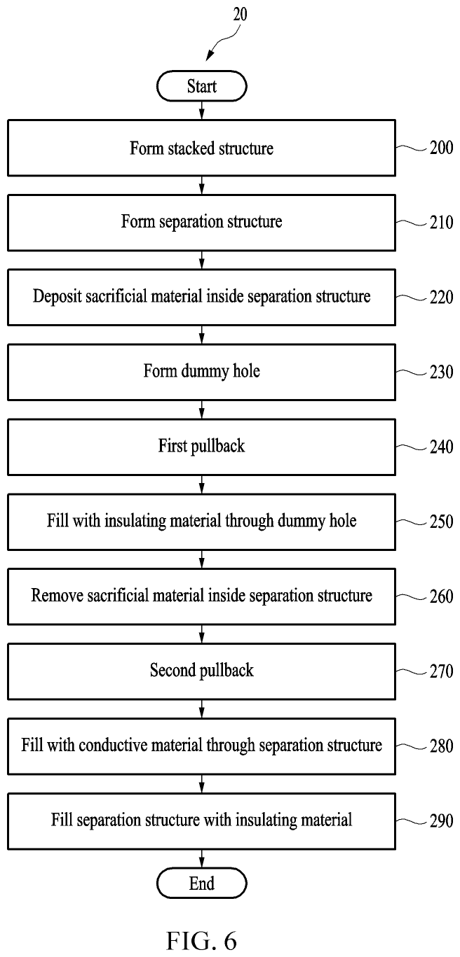

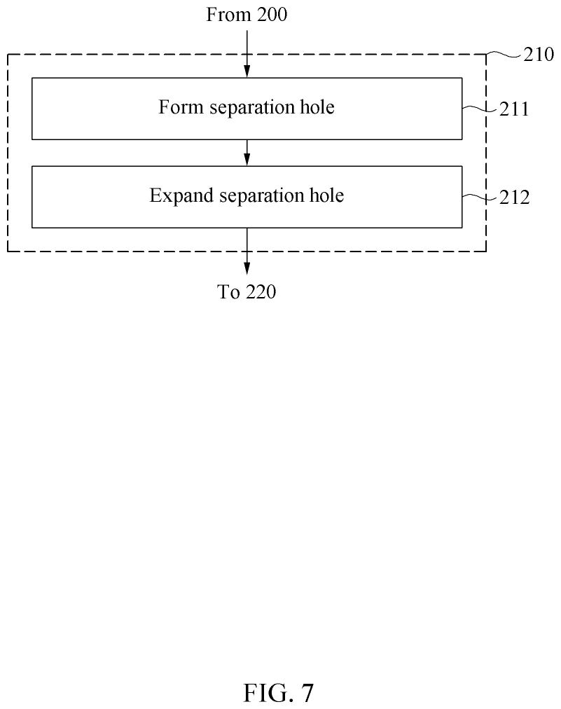

FIG. 6 is a flowchart of a method of manufacturing a semiconductor device according to an example embodiment. FIG. 7 is a flowchart of an operation of forming a separation structure in the method of manufacturing a semiconductor device according to an example embodiment. Meanwhile, FIGS. 6 and 7 are merely examples, and the order of the operations of the method of manufacturing a semiconductor device is not limited to the order shown in FIGS. 6 and 7. For example, one operation may be performed before or simultaneously with another operation. FIGS. 8A, 8B, 9A, 9B, 10A, 10B, 11A, 11B, 12A, 12B, 13A, 13B, 14A, 14B, 15A, 15B, 16A, and 16B are schematic plan views or cross-sectional views of a semiconductor device, illustrating a method of manufacturing a semiconductor device according to an embodiment.

Hereinafter, a method 20 of manufacturing a semiconductor device according to an embodiment is described with reference to FIGS. 6 to 16B.

In an embodiment, the method 20 of manufacturing a semiconductor device may be a method for manufacturing the semiconductor device 10 described with reference to FIGS. 4 to 5B. For example, the semiconductor device 10 of FIGS. 4 to 5B may be manufactured by the method 20 of manufacturing a semiconductor device.

The method 20 of manufacturing a semiconductor device according to an embodiment may include operation 200 of forming a stacked structure, operation 210 of forming a separation structure, operation 220 of depositing a sacrificial material inside the separation structure, operation 230 of forming a dummy hole, operation 240 of performing a first pullback, operation 250 of filling with an insulating material through the dummy hole, operation 260 of removing the sacrificial material inside the separation structure, operation 270 of performing a second pullback, operation 280 of filling with a conductive material through the separation structure, and operation 290 of filling the separation structure with an insulating material.

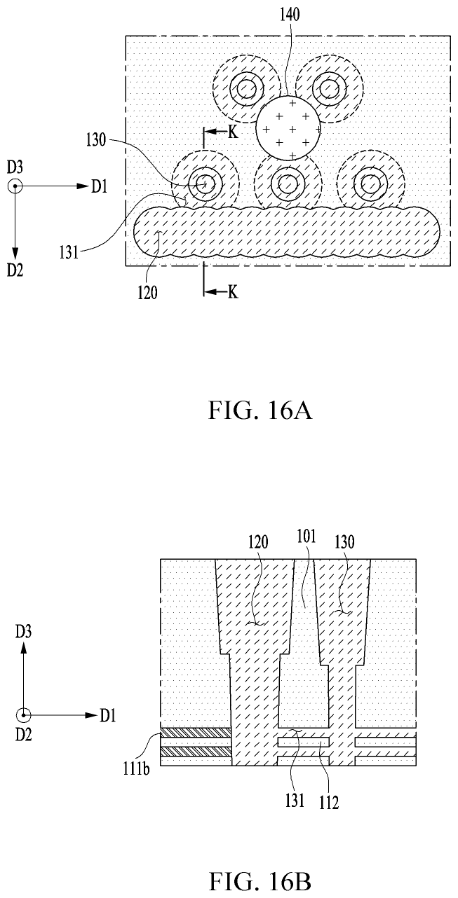

In an embodiment, referring to FIGS. 6, 7, 8A, and 8B, operation 200 of forming a stacked structure may be an operation of forming a stacked structure 110 including a plurality of sacrificial insulating layers 111a and a plurality of interlayer insulating layers 112 alternately stacked on a substrate (e.g., the semiconductor substrate 3010 of FIG. 2B). The sacrificial insulating layers 111a and the interlayer insulating layers 112 may include different materials. For example, the sacrificial insulating layers 111a may include a material that may be etched with etch selectivity under predetermined etching conditions with respect to the interlayer insulating layers 112. For example, the sacrificial insulating layers 111a may include silicon nitride, and the interlayer insulating layers 112 may include silicon oxide. A portion of the sacrificial insulating layers 111a may be replaced by gate electrodes (e.g., gate electrode 111b of FIG. 16B) through a subsequent process.

In an embodiment, operation 210 of forming a separation structure may be an operation of forming a separation structure 120 penetrating the stacked structure 110. The separation structure 120 may be formed to extend lengthwise in the first horizontal direction D1. In an embodiment, operation 210 of forming a separation structure may include operation 211 of forming a separation hole and operation 212 of expanding the separation hole.

In an embodiment, operation 211 of forming a separation hole may be an operation of forming a plurality of separation holes 121 penetrating the stacked structure 110, the separation holes arranged in the horizontal direction D1. For example, as shown in FIG. 8A, the plurality of separation holes 121 may be formed to be spaced apart from each other in the first horizontal direction D1. For example, the separation holes 121 may be formed through a dry etching process and/or a wet etching process. For example, the process of forming the separation holes 121 may include a process of removing the sacrificial insulating layers 111a, the interlayer insulating layers 112, polysilicon layers, and/or carbon layers.

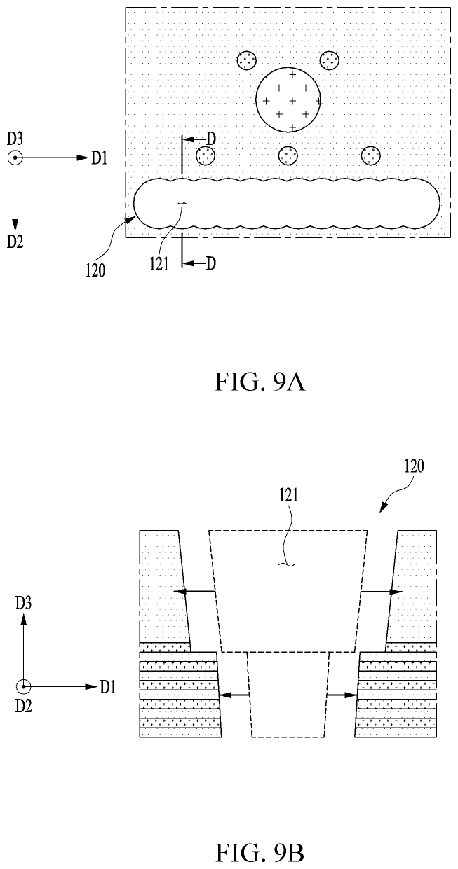

In an embodiment, operation 212 of expanding the separation hole may be an operation of forming the separation structure 120 by expanding the plurality of separation holes 121 in a radial direction so that adjacent separation holes 121 may communicate with each other. For example, the size of the separation holes 121 may be expanded in the radial direction through a wet etching process. For example, the separation holes 121 may be expanded so that adjacent separation holes 121 may overlap each other. As shown in FIG. 9A, the plurality of separation holes 121 may communicate with each other and form the separation structure 120 formed in the first horizontal direction D1. However, this is merely an example, and the separation structure 120 may be formed as a single linear structure.

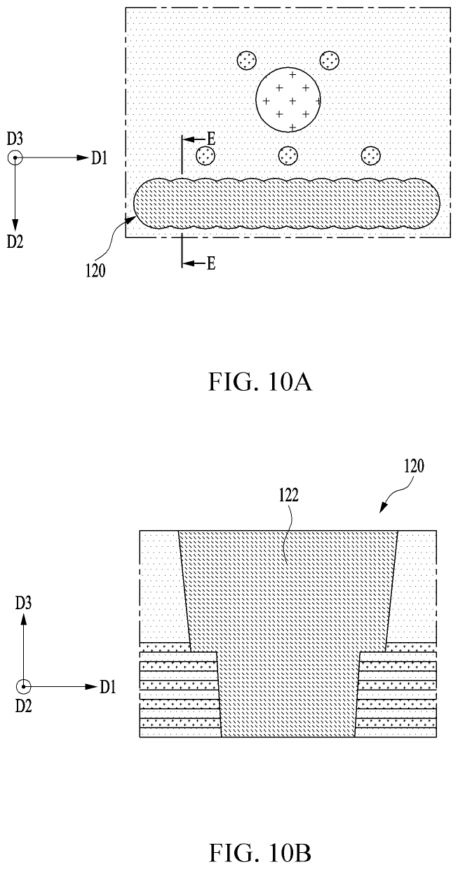

In an embodiment, through operation 220 of depositing a sacrificial material inside the separation structure, the separation structure 120 may be filled with a sacrificial material 122. For example, the sacrificial material 122 may fill the space inside the separation structure 120 as shown in FIG. 10B, or the sacrificial material 122 may be deposited in the form of a film on the inner surface of the separation structure 120. The sacrificial material 122 may include silicon oxide, polysilicon, and/or carbon. However, these are merely examples, and the type of sacrificial material 122 is not limited thereto.

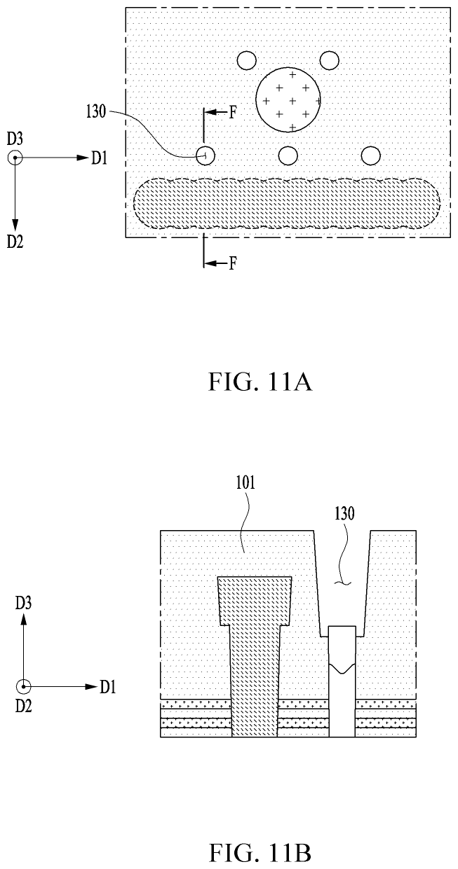

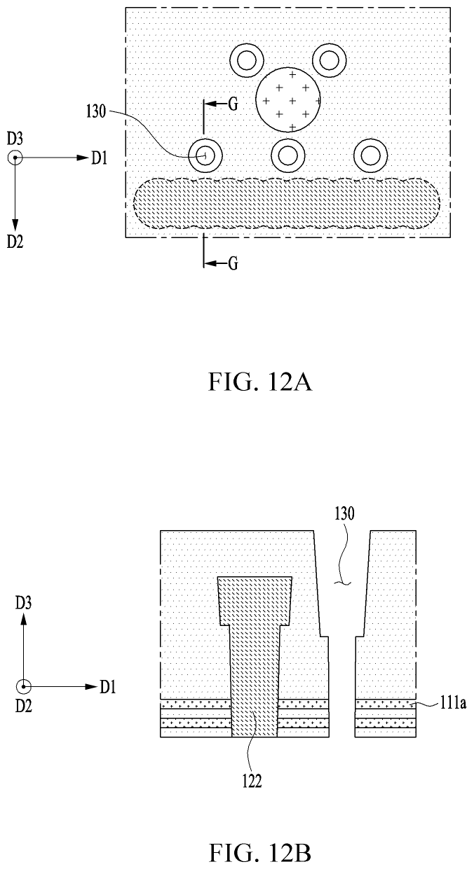

In an embodiment, operation 230 of forming a dummy hole may be an operation of forming a plurality of dummy holes 130 penetrating the stacked structure 110. For example, the plurality of dummy holes 130 may be formed in a stepped area (e.g., the stepped area A2 of FIGS. 2B and 3A). For example, the plurality of dummy holes 130 may be arranged to form a designated pattern. For example, operation 230 of forming a dummy hole may include an operation of stacking an insulating mold structure 101 on the top of the stacked structure 110, an operation of opening an upper portion of the dummy hole 130 (e.g., FIG. 11B), and an operation of forming the dummy hole 130 penetrating the stacked structure 110 through the opened upper portion (e.g., FIG. 12B). For example, the operation of opening an upper portion of the dummy hole 130 may be performed using a dry etching process, and the operation of forming the dummy hole 130 penetrating the stacked structure 110 through the opened upper portion may be performed using a wet etching process. However, this is merely an example, and operation 230 of forming a dummy hole is not limited thereto. Additionally, operation 230 of forming a dummy hole does not have to be performed after operation 210 of forming a separation structure and operation 220 of depositing a sacrificial material inside the separation structure. For example, operation 230 of forming a dummy hole may be performed before or simultaneously with operation 210 of forming a separation structure and/or operation 220 of depositing a sacrificial material inside the separation structure. For example, operation 230 of forming a dummy hole may be performed simultaneously with operation 211 of forming a separation hole.

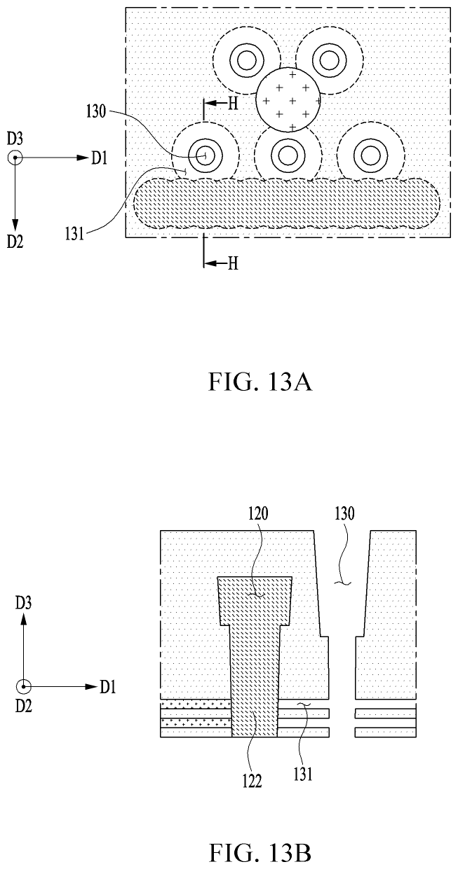

In an embodiment, operation 240 of performing a first pullback may be an operation of removing a portion of the plurality of sacrificial insulating layers 111a connected to the plurality of dummy holes 130 through the plurality of dummy holes 130. Operation 240 of performing a first pullback may be performed after the sacrificial material is deposited inside the separation structure 120. In operation 240 of performing a first pullback, a selectivity ratio may be set so that only the sacrificial insulating layers 111a may be removed and the sacrificial material 122 deposited inside the separation structure 120 may not be removed. For example, as shown in FIG. 13B, only the sacrificial insulating layers 111a connected to the dummy hole 130 may be removed, and the sacrificial material 122 deposited inside the separation structure 120 may not be removed. The sacrificial insulating layers 111a connected to the dummy hole 130 may be removed within a designated range of radius from the dummy hole 130. As the sacrificial insulating layers 11a connected to the dummy hole 130 are removed in the designated range of radius from the dummy hole 130, a protruding structure 131 communicating with the dummy hole 130 may be formed.

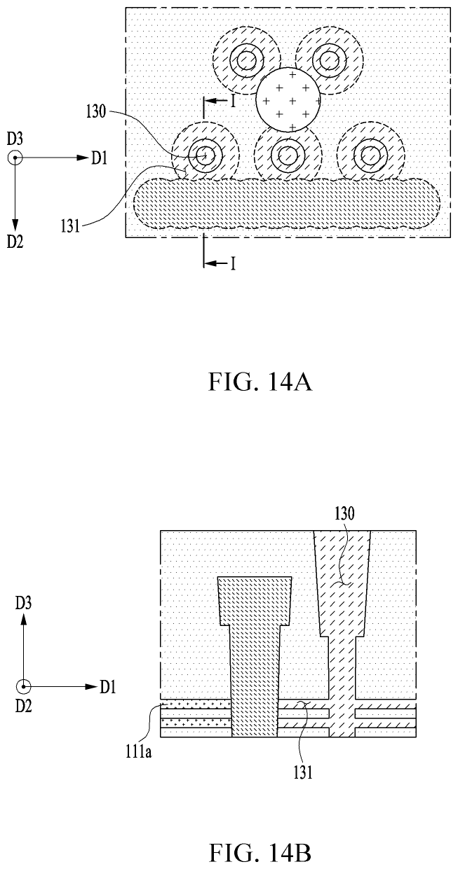

In an embodiment, operation 250 of filling with an insulating material through the dummy hole may be an operation of filling, through the plurality of dummy holes 130, with an insulating material (e.g., silicon oxide) at positions of the plurality of sacrificial insulating layers 111a removed in operation 240 of performing a first pullback. In operation 250 of filling with an insulating material through the dummy hole, the dummy hole 130 and the protruding structure 131 formed in operation 240 of performing a first pullback may be filled with the insulating material, as shown in FIG. 14B. For example, the protruding structure 131 may be filled with the insulating material using an atomic layer deposition (ALD) process. For example, in the process of filling the protruding structure 131 with an insulating material, a seam or a void may be formed inside the protruding structure 131.

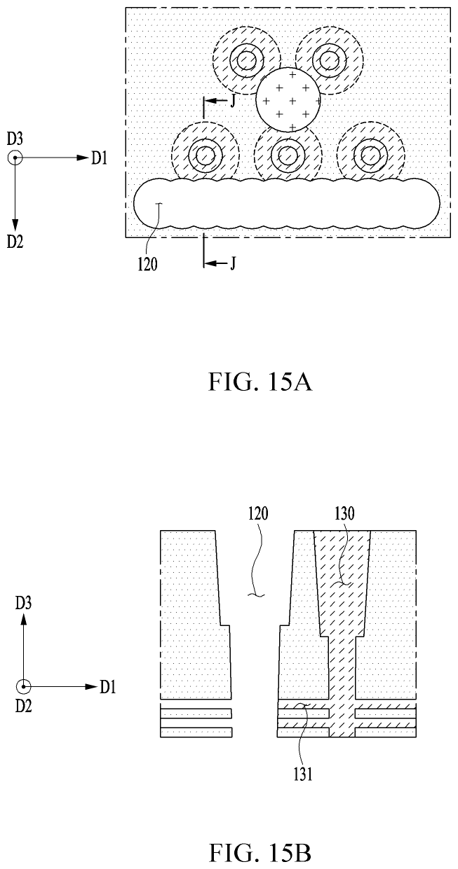

In an embodiment, operation 260 of removing the sacrificial material inside the separation structure may be an operation of removing the sacrificial material 122 deposited inside the separation structure 120 (e.g., FIG. 15B). For example, operation 260 of removing the sacrificial material inside the separation structure may include an operation of opening an upper portion of the separation structure 120, and an operation of removing the sacrificial material inside the separation structure 120 through the opened upper portion of the separation structure 120. For example, the operation of opening the upper part of the separation structure 120 may be performed using a dry etching process, and the operation of removing the sacrificial material inside the separation structure 120 through the opened upper portion of the separation structure 120 may be performed using a wet etching process. However, this is merely an example, and operation 260 of removing the sacrificial material inside the separation structure is not limited thereto.

In an embodiment, operation 270 of performing a second pullback may be an operation of removing another portion of the plurality of sacrificial insulating layers 111a connected to the separation structure 120 through the separation structure 120. For example, in operation 270 of performing a second pullback, a selectivity ratio may be set so that only the sacrificial insulating layers 111a may be removed and the insulating material deposited inside the dummy hole 130 and/or the protruding structure 131 may not be removed. For example, as shown in FIG. 15B, only the sacrificial insulating layers 111a connected to the separation structure 120 may be removed, and the insulating material deposited inside the dummy hole 130 and/or the protruding structure 131 may not be removed.

In an embodiment, operation 280 of filling with a conductive material through the separation structure may be an operation of filling, through the separation structure 120, with a conductive material at positions of the plurality of sacrificial insulating layers 111a removed in operation 270 of performing a second pullback. Through operation 270 of performing a second pullback and operation 280 of filling with a conductive material through the separation structure, the sacrificial insulating layers 111a may be substituted with the conductive material to form the gate electrodes 111b. Accordingly, as shown in FIG. 16B, the gate electrodes 111b may be formed at the positions of the sacrificial insulating layers 111a.

In an embodiment, through operation 290 of filling the separation structure with an insulating material, the separation structure 120 may be filled with an insulating material (e.g., silicon oxide). For example, the insulating material may fill the space inside the separation structure 120, as shown in FIG. 16B. For example, the separation structure 120, the dummy hole 130, the protruding structure 131, the interlayer insulating layers 112, and/or the insulating mold structure 101 may include substantially the same insulating material. Although FIG. 16B shows the boundary lines between the components for ease of description, the separation structure 120, the dummy hole 130, the protruding structure 131, the interlayer insulating layers 112, and/or the insulating mold structure 101 are filled with substantially the same insulating material (e.g., silicon oxide), and thus, it may seem that there is no boundary therebetween. In example embodiments, upper surfaces of the separation structures 120 and upper surfaces of the dummy holes 130 may be at the same vertical level. For example, upper surfaces of the separation structures 120 and the dummy holes 130 may be coplanar with an upper surface of the insulating mold structure 101. In example embodiments, the insulating mold structure 101 may contact side surfaces of the separation structures 120 and the dummy holes 130. The gate electrodes 111b and the interlayer insulating layers 112 may contact side surfaces of the separation structures 120.

In an embodiment, the method 20 of manufacturing a semiconductor device may further include an operation of forming a cell contact plug 140 penetrating the stacked structure 110. The operation of forming a cell contact plug 140 may be performed after, before, and/or simultaneously with the method 20 of manufacturing a semiconductor device described above. For example, the operation of forming a cell contact plug 140 may be performed simultaneously with operation 211 of forming a separation hole and operation 230 of forming a dummy hole.

In a comparative example, the dummy hole may be expanded first, and then the separation structure may be opened and expanded. In the comparative example, when the chemicals used to expand the separation structure meet the seam of the protruding structure, some areas of the protruding structure and the dummy hole may be unintentionally removed. In this case, the support force of the protruding structure and the dummy hole may be insufficient, causing the stacked structure to collapse. Additionally, in the subsequent process of substituting the sacrificial insulating layers with a conductive material, the conductive material may flow into the area where the protruding structure and the dummy hole are removed, and the residue of the conductive material may cause bridge defects that connect word lines. Meanwhile, according to the method 20 of manufacturing a semiconductor device according to an embodiment, the separation structure 120 is opened and expanded to deposit the sacrificial material 122 therein before expanding the dummy hole 130. Thus, a node may be physically separated between the dummy hole 130 and the separation structure 120 by the sacrificial material 122 in the process of expanding the dummy hole 130, which may consequently reduce the word line bridge defects. In addition, since the node is physically separated between the dummy hole 130 and the separation structure 120 by the sacrificial material 122, the separation structure 120 and the protruding structure 131 may be formed to overlap each other, and accordingly, the distance between two adjacent separation structures 120 in the second horizontal direction D2 may be further reduced. In addition, in the process of performing a pullback, the unintentional removal of the dummy hole 130 and the protruding structure 131 may be reduced, and the collapse of the stacked structure 110 may also be reduced.

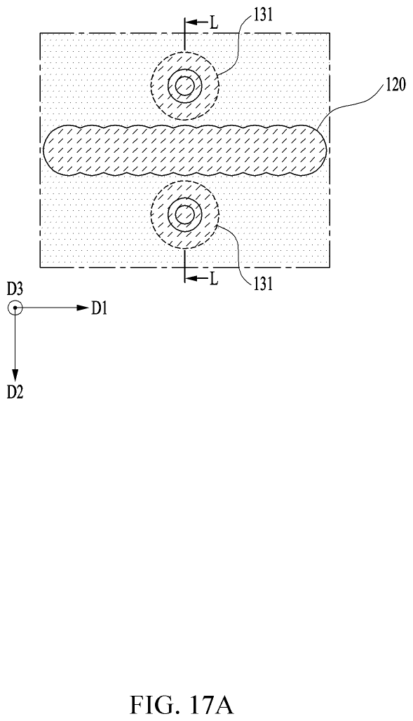

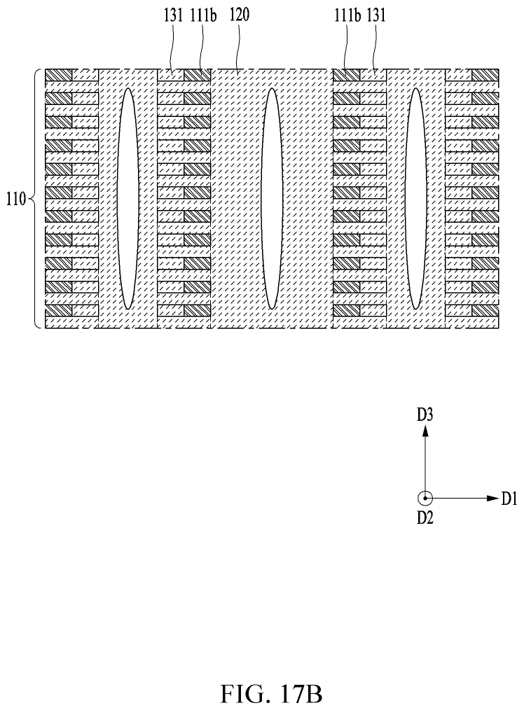

FIG. 17A is a plan view illustrating a portion of a semiconductor device according to an embodiment. For example, FIG. 17A may be a plan view of a stepped area (e.g., the stepped area A2 of FIGS. 2B and 3A) in a semiconductor device according to an embodiment. FIG. 17B is a cross-sectional view of a semiconductor device, taken along line L-L of FIG. 17A, according to an embodiment. FIG. 17B may be understood as a diagram with lines added to the boundaries of the components for ease of description.

Referring to FIGS. 17A and 17B, in an embodiment, the separation structure 120 and the protruding structure 131 may be positioned not to overlap each other. In this case, the gate electrodes 111b may be positioned between the separation structure 120 and the plurality of protruding structures 131 based on the cross-section of the stacked structure 110 in the vertical direction D3.

A number of embodiments have been described above. Nevertheless, it should be understood that various modifications and variations may be made to these embodiments. For example, suitable results may be achieved if the described techniques are performed in a different order, and/or if components in a described system, architecture, device, or circuit are combined in a different manner, and/or replaced or supplemented by other components or their equivalents. Accordingly, other implementations are within the scope of the following claims.

What is claimed is:

1. A method of manufacturing a semiconductor device, the method comprising:
forming a stacked structure comprising a plurality of sacrificial insulating layers and a plurality of interlayer insulating layers alternately stacked on a substrate;
forming a separation structure penetrating the stacked structure;
depositing a sacrificial material inside the separation structure;
forming a plurality of dummy holes penetrating the stacked structure; and
performing a first pullback to remove a first portion of the plurality of sacrificial insulating layers connected to the plurality of dummy holes through the plurality of dummy holes, after the sacrificial material is deposited inside the separation structure.

2. The method of claim 1, wherein the forming of the separation structure comprises:
forming a plurality of separation holes penetrating the stacked structure, the separation holes arranged in a horizontal direction; and
forming the separation structure by expanding the plurality of separation holes in a radial direction so that adjacent separation holes communicate with each other.

3. The method of claim 1, wherein in the first pullback, the sacrificial material deposited inside the separation structure is not removed.

4. The method of claim 1, further comprising:
filling, through the plurality of dummy holes, with an insulating material at positions of the plurality of sacrificial insulating layers removed in the first pullback.

5. The method of claim 4, further comprising:
removing the sacrificial material deposited inside the separation structure.

6. The method of claim 5, further comprising:
performing a second pullback to remove a second portion of the plurality of sacrificial insulating layers connected to the separation structure through the separation structure.

7. The method of claim 6, further comprising:
filling, through the separation structure, with a conductive material at positions of the plurality of sacrificial insulating layers removed in the second pullback.

8. The method of claim 7, further comprising:
filling the separation structure with an insulating material.

9. The method of claim 8, wherein the separation structure and the plurality of dummy holes are filled with a same insulating material.

10. The method of claim 5, wherein the removing of the sacrificial material deposited inside the separation structure comprises:
opening an upper portion of the separation structure; and
removing the sacrificial material inside the separation structure through the opened upper portion of the separation structure.

11. The method of claim 1,
wherein the stacked structure comprises a memory cell array area and a stepped area, and
wherein the dummy holes are formed in the stepped area.

12. The method of claim 1, wherein the plurality of dummy holes are arranged to form a designated pattern.

13. The method of claim 1, further comprising:
forming a cell contact plug penetrating the stacked structure.

14. The method of claim 13, wherein the cell contact plug is positioned between the plurality of dummy holes.

15. A semiconductor device manufactured by the method of claim 1.

16. A semiconductor device comprising:
a stacked structure comprising a plurality of gate electrodes and a plurality of interlayer insulating layers alternately stacked on a substrate;
a separation structure comprising a plurality of separation holes penetrating the stacked structure, wherein the separation structure is formed such that separation holes adjacent in a horizontal direction communicate with each other;
a plurality of dummy holes penetrating the stacked structure at positions adjacent to the separation structure; and
a plurality of protruding structures protruding in a radial direction from the plurality of dummy holes at heights corresponding to the plurality of gate electrodes and touching the separation structure,
wherein the separation structure, the plurality of dummy holes, and the plurality of protruding structures comprise an insulating material.

17. The semiconductor device of claim 16, wherein the separation structure and the plurality of protruding structures are seamlessly and continuously connected based on a vertical cross section of the stacked structure.

18. The semiconductor device of claim 16, wherein the separation structure and the plurality of protruding structures are directly connected so that a conductive material is not positioned therebetween, based on a vertical cross section of the stacked structure.

19. The semiconductor device of claim 16, wherein an interval between two protruding structures positioned adjacent to each other in a horizontal direction is less than or equal to 250 nanometers (nm).

20. The semiconductor device of claim 16,
wherein the stacked structure comprises a memory cell array area and a stepped area, and
wherein the separation structure, the plurality of dummy holes, and the plurality of protruding structures are formed in the stepped area.
